(19) United States
(12) Patent Application Publication
(10) Pub. No.: US 2024/0179887 A1
(43) Pub. Date: May 30, 2024

(54) MEMORY-ELEMENT-INCLUDING SEMICONDUCTOR DEVICE

(71) Applicant: Unisantis Electronics Singapore Pte. Ltd., Singapore (SG)

(72) Inventors: Nozomu HARADA, Tokyo (JP); Masakazu KAKUMU, Tokyo (JP); Koji SAKUI, Tokyo (JP)

(21) Appl. No.: 18/520,130

(22) Filed: Nov. 27, 2023

(30) Foreign Application Priority Data
Nov. 28, 2022 (WO) PCT/JP2022/043781

(51) Int. Cl. H10B 12/00; G11C 11/404; G11C 11/4096

(52) U.S. Cl. CPC H10B 12/20; G11C 11/404; G11C 11/4096

(57) ABSTRACT

In a memory cell including a first gate insulating layer 5 and a first gate conductor layer 6 surrounding a P layer 3a constituting a lower portion of a pillar-shaped P layer 3 standing on a P layer substrate 1, a second gate insulating layer 9 surrounding a P layer 3b constituting an upper portion of the P layer 3, a second gate conductor layer 10, and N⁺ layers 11a and 11b at both ends of the P layer 3b and a MOS transistor including a pillar-shaped P layer 3A standing on a P layer substrate 1a connecting to the same P layer substrate 1, a third gate insulating layer 9a surrounding an upper P layer 3ba of the P layer 3A, a third gate conductor layer 10a, and N⁺ layers 11aa and 11ba at both ends of the P layer 3ba, bottom portions and top portions of the P layer 3 and the P layer 3A are located at substantially the same heights of line A and line C, respectively, in a perpendicular direction, and bottom portions of the P layer 3b and the P layer 3ba are located at substantially the same height of line B.

### CROSS-REFERENCE TO RELATED APPLICATIONS

This application claims priority to PCT/JP2022/043781, filed Nov. 28, 2022, the entire content of which is incorporated herein by reference.

### BACKGROUND OF THE INVENTION

### 1. Field of the Invention

The present invention relates to a memory-element-including semiconductor device.

### 2. Description of the Related Art

In recent years, in the development of large-scale integration (LSI) technologies, there have been demands for higher degree of integration, higher performance, lower power consumption, and higher functionality of memory-element-including semiconductor devices.

Typical planar MOS transistors have a channel that extends in a horizontal direction along an upper surface of a semiconductor substrate. In contrast, surrounding gate transistors (SGTs) have a channel that extends in a direction perpendicular to an upper surface of a semiconductor substrate (refer to, for example, Hiroshi Takato, Kazumasa Sunouchi, Naoko Okabe, Akihiro Nitayama, Katsuhiko Hieda, Fumio Horiguchi, and Fujio Masuoka: IEEE Transaction on Electron Devices, Vol. 38, No. 3, pp. 573-578 (1991)). For this reason, SGTs enable an increase in the density of semiconductor devices compared with planar MOS transistors. Such SGTs can be used as select transistors to achieve an increase in the degree of integration of memories, such as a dynamic random access memory (DRAM) to which a capacitor is connected (refer to, for example, H. Chung, H. Kim, H. Kim, K. Kim, S. Kim, K. W. Song, J. Kim, Y. C. Oh, Y. Hwang, H. Hong, G. Jin, and C. Chung: “4F2 DRAM Cell with Vertical Pillar Transistor (VPT)”, 2011 Proceeding of the European Solid-State Device Research Conference, (2011)); a phase change memory (PCM) to which a resistance-change element is connected (refer to, for example, H. S. Philip Wong, S. Raoux, S. Kim, Jiale Liang, J. R. Reifenberg, B. Rajendran, M. Asheghi and K. E. Goodson: “Phase Change Memory”, Proceeding of IEEE, Vol. 98, No. 12, December, pp. 2201-2227 (2010)); a resistive random access memory (RRAM) (refer to, for example, K. Tsunoda, K. Kinoshita, H. Noshiro, Y. Yamazaki, T. Iizuka, Y. Ito, A. Takahashi, A. Okano, Y. Sato, T. Fukano, M. Aoki, and Y. Sugiyama: “Low Power and high Speed Switching of Ti-doped NiO ReRAM under the Unipolar Voltage Source of less than 3V”, IEDM (2007)); and a magneto-resistive random access memory (MRAM) in which the orientation of the magnetic spin is changed with a current to change the resistance (refer to, for example, W. Kang, L. Zhang, J. Klein, Y. Zhang, D. Ravelosona, and W. Zhao: “Reconfigurable Codesign of STT-MRAM Under Process Variations in Deeply Scaled Technology”, IEEE Transaction on Electron Devices, pp. 1-9 (2015)). There are also, for example, a capacitor-less DRAM memory cell constituted by a single MOS transistor (refer to M. G. Ertosun, K. Lim, C. Park, J. Oh, P. Kirsch, and K. C. Saraswat: “Novel Capacitorless Single-Transistor Charge-Trap DRAM (1T CT DRAM) Utilizing Electron”, IEEE Electron Device Letter, Vol. 31, No. 5, pp. 405-407 (2010)); and a DRAM memory cell having two groove portions for storing carriers and two gate electrodes (refer to Md. Hasan Raza Ansari, Nupur Navlakha, Jae Yoon Lee, Seongjae Cho, “Double-Gate Junctionless 1T DRAM With Physical Barriers for Retention Improvement” IEEE Trans, on Electron Devices vol. 67, pp. 1471-1479 (2020)). However, capacitor-less DRAMs have a problem in that they are considerably affected by, in the floating bodies, coupling of gate electrodes due to word lines, and a sufficient voltage margin cannot be provided. This application relates to a semiconductor-element-including memory device that does not include resistance-change elements or capacitors and that can be constituted by MOS transistors alone.

### SUMMARY OF THE INVENTION

In a single transistor DRAM (a gain cell) that is a capacitor-less memory device, capacitive coupling between the word line and the body including an element in a floating state is strong, and therefore, there is a problem in that, when the electric potential of the word line is changed at the time of reading or writing of data, the change is transmitted directly as noise to the body of the semiconductor substrate. This causes problems of erroneous reading or erroneous writing of stored data and makes it difficult to put such a capacitor-less single-transistor DRAM into practical use. It is necessary to address the above problems and produce memory cells and MOS transistors of a peripheral logic circuit at high density and low cost.

In order to address the above problems, a memory-element-including semiconductor device according to a first invention is a semiconductor device including:
a memory element; and
a MOS transistor,
wherein the memory element includes
a first semiconductor pillar that stands on a substrate in a direction perpendicular to the substrate,
a first impurity region connecting to a bottom portion of the first semiconductor pillar,
a first gate insulating layer in contact with a lower portion of the first semiconductor pillar,
a first gate conductor layer in contact with the first gate insulating layer and composed of one part or two parts in plan view or in the perpendicular direction,
a first insulating layer disposed between the first impurity region and the first gate conductor layer,
a second insulating layer disposed on the first gate conductor layer and surrounding the first semiconductor pillar,
a second gate insulating layer covering, in the perpendicular direction, an upper surface of the first semiconductor pillar located above the first gate insulating layer or the upper surface and both side surfaces continuous with the upper surface,
a second gate conductor layer covering the second gate insulating layer, and
a second impurity region and a third impurity region disposed at both ends of a portion of the first semiconductor pillar, the portion being not covered with the second gate insulating layer, in a horizontal direction,
the MOS transistor includes
a second semiconductor pillar that stands on the substrate in the direction perpendicular to the substrate,
a first material layer surrounding a lower part of the second semiconductor pillar and formed of, from a bottom, a third insulating layer, an intermediate material layer made of an insulating material or a conductor material, and a fourth insulating layer,
a third gate insulating layer covering, in the perpendicular direction, an upper surface of the second semiconductor pillar located above the first material layer or the upper surface and both side surfaces,
a third gate conductor layer covering the third gate insulating layer, and
a fourth impurity region and a fifth impurity region disposed at both ends of a portion of the second semiconductor pillar, the portion being not covered with the third gate insulating layer, in the horizontal direction, and
an upper surface of the second insulating layer and an upper surface of the first material layer are located at substantially the same position in the perpendicular direction.

According to a second invention, in the first invention, the upper surface of the first semiconductor pillar is substantially flush with or located below the upper surface of the second semiconductor pillar in the perpendicular direction.

According to a third invention, in the first invention, the intermediate material layer is made of an insulating material.

According to a fourth invention, in the first invention, the intermediate material layer is formed of an insulating layer surrounding a lower portion of the second semiconductor pillar and a conductor layer surrounding the insulating layer, and a voltage that is constant or changes with time is applied to the conductor layer.

According to a fifth invention, in the fourth invention, the memory-element-including semiconductor device includes a sixth impurity region connecting to the bottom portion of the second semiconductor pillar.

According to a sixth invention, in the first invention, the first gate insulating layer and the first insulating layer are made of the same material.

According to a seventh invention, in the first invention, a transistor composed of an upper portion of the first semiconductor pillar, the second gate insulating layer, the second gate conductor layer, the second impurity region, and the third impurity region of the memory element is a planar MOS transistor, and the MOS transistor is also a planar MOS transistor.

According to an eighth invention, in the first invention, a transistor composed of an upper portion of the first semiconductor pillar, the second gate insulating layer, the second gate conductor layer, the second impurity region, and the third impurity region of the memory element is a fin MOS transistor, and the MOS transistor is also a fin MOS transistor.

According to a ninth invention, in the first invention, the first impurity region connects to a bottom portion of a semiconductor pillar of another memory cell adjacent to the first semiconductor pillar.

According to a tenth invention, in the first invention, the first impurity region is isolated from an impurity layer in a bottom portion of a semiconductor pillar of another memory cell adjacent to the first semiconductor pillar.

According to an eleventh invention, in the first invention, the two parts of the first gate conductor layer composed of two parts in the perpendicular direction are configured to be driven synchronously or asynchronously.

According to a twelfth invention, in the first invention, the two parts of the first gate conductor layer composed of two parts in plan view are configured to be driven synchronously or asynchronously.

According to a thirteenth invention, in the first invention, the first semiconductor pillar, the first and second gate insulating layers, the first to third impurity regions, and the first and second gate conductor layers are configured to perform
a memory write operation of controlling voltages applied to the first impurity region, the second impurity region, the third impurity region, the first gate conductor layer, and the second gate conductor layer to generate, in an upper portion of the first semiconductor pillar, a group of electrons and a group of positive holes by an impact ionization phenomenon using a current flowing between the second impurity region and the third impurity region or by a gate-induced drain-leakage current and cause, of the generated group of electrons and the generated group of positive holes, a portion or entirety of the group of electrons or the group of positive holes serving as majority carriers to remain mainly in the first semiconductor pillar in contact with the first gate insulating layer, and
a memory erase operation of discharging the group of electrons or the group of positive holes serving as the remaining majority carriers from at least the first impurity region, the second impurity region, and the third impurity region.

According to a fourteenth invention, in the first invention, the bottom portion of the first semiconductor pillar and a bottom portion of the second semiconductor pillar are located at substantially the same position in the perpendicular direction.

### BRIEF DESCRIPTION OF THE DRAWINGS

FIG. 1 is a sectional structural view of a semiconductor-element-including memory device according to an embodiment.

FIGS. 2A, 2B, and 2C are explanatory views of a write operation in a semiconductor-element-including memory device according to an embodiment.

FIGS. 3A, 3B, and 3C are explanatory views of an erase operation in a semiconductor-element-including memory device according to an embodiment.

FIGS. 4A and 4B are explanatory views of structures of a memory cell and a MOS transistor of a logic circuit that are formed on the same substrate, according to the embodiment.

FIGS. 5A and 5B are explanatory views of structures of a memory cell and a MOS transistor of a logic circuit that are formed on the same substrate, according to the embodiment.

FIGS. 6A and 6B are explanatory views of structures of a memory cell and a MOS transistor of a logic circuit that are formed on the same substrate, according to the embodiment.

FIGS. 7AA and 7AB are explanatory views of a production method in which a memory cell and a MOS transistor of a logic circuit according to the embodiment are formed on the same substrate.

FIGS. 7BA and 7BB are explanatory views of a production method in which a memory cell and a MOS transistor of a logic circuit according to the embodiment are formed on the same substrate.

FIGS. 7CA and 7CB are explanatory views of a production method in which a memory cell and a MOS transistor of a logic circuit according to the embodiment are formed on the same substrate.

FIGS. 7DA and 7DB are explanatory views of a production method in which a memory cell and a MOS transistor of a logic circuit according to the embodiment are formed on the same substrate.

FIGS. 7EA and 7EB are explanatory views of a production method in which a memory cell and a MOS transistor of a logic circuit according to the embodiment are formed on the same substrate.

FIGS. 7FA and 7FB are explanatory views of a production method in which a memory cell and a MOS transistor of a logic circuit according to the embodiment are formed on the same substrate.

FIGS. 7GA and 7GB are explanatory views of a production method in which a memory cell and a MOS transistor of a logic circuit according to the embodiment are formed on the same substrate.

FIGS. 7HA and 7HB are explanatory views of a production method in which a memory cell and a MOS transistor of a logic circuit according to the embodiment are formed on the same substrate.

FIGS. 7IA and 7IB are explanatory views of a production method in which a memory cell and a MOS transistor of a logic circuit according to the embodiment are formed on the same substrate.

### DESCRIPTION OF THE PREFERRED EMBODIMENTS

A semiconductor-element-including memory device according to an embodiment of the present invention and a method for producing the semiconductor-element-including memory device will be described below with reference to the drawings.

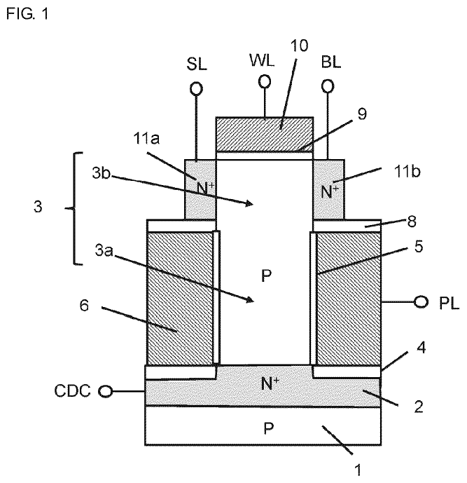

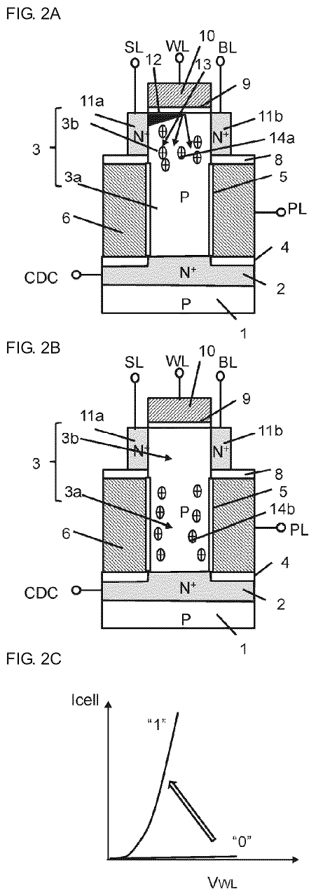

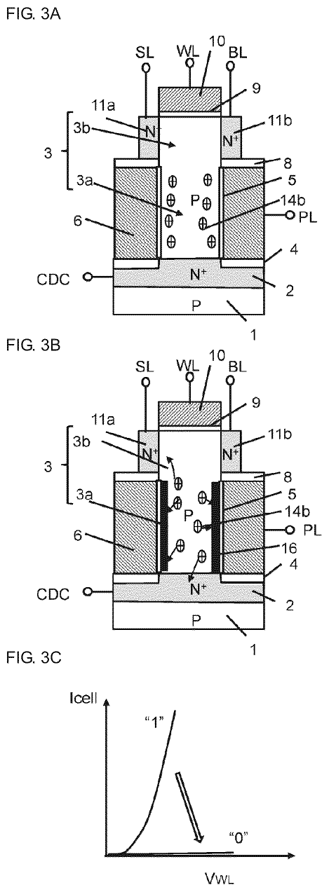

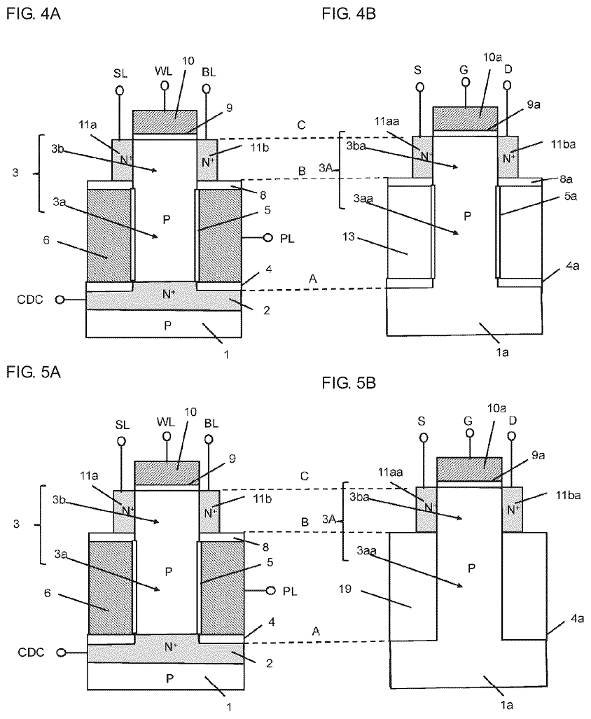

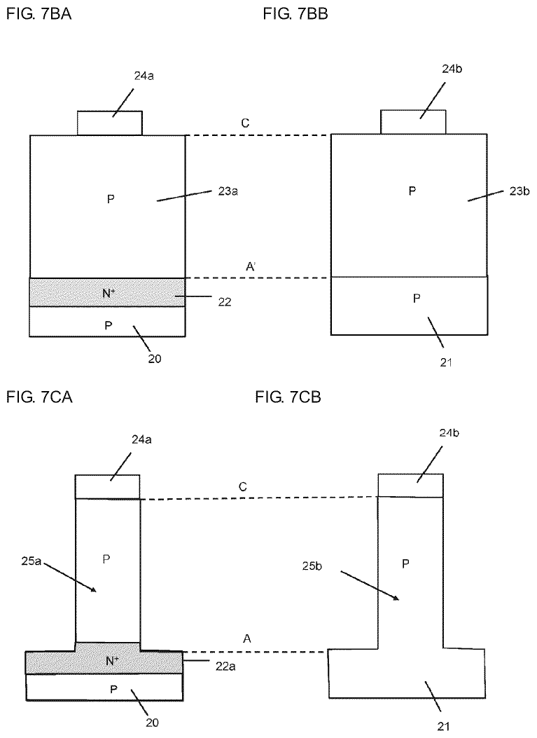

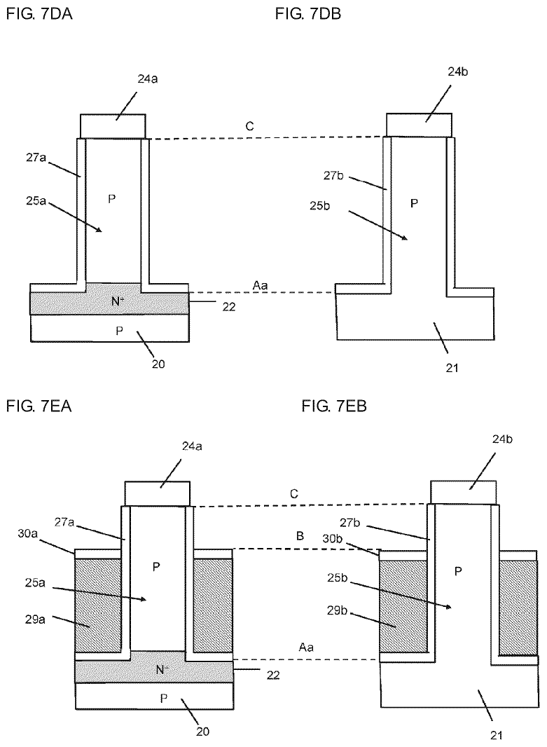

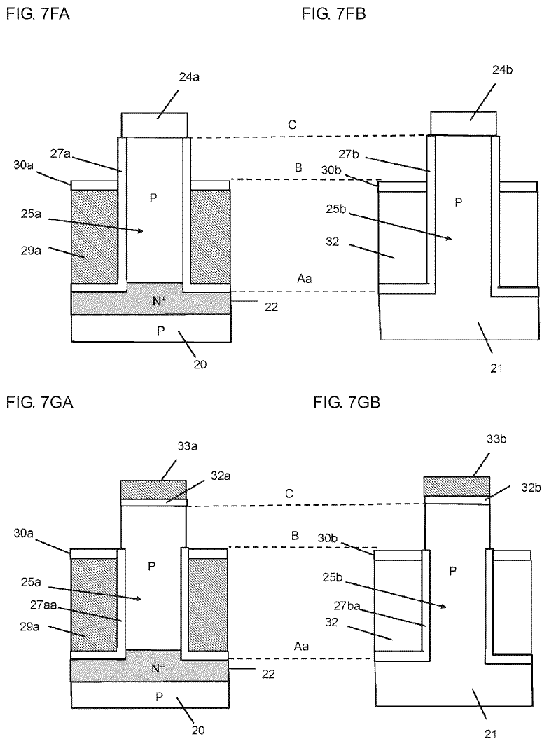

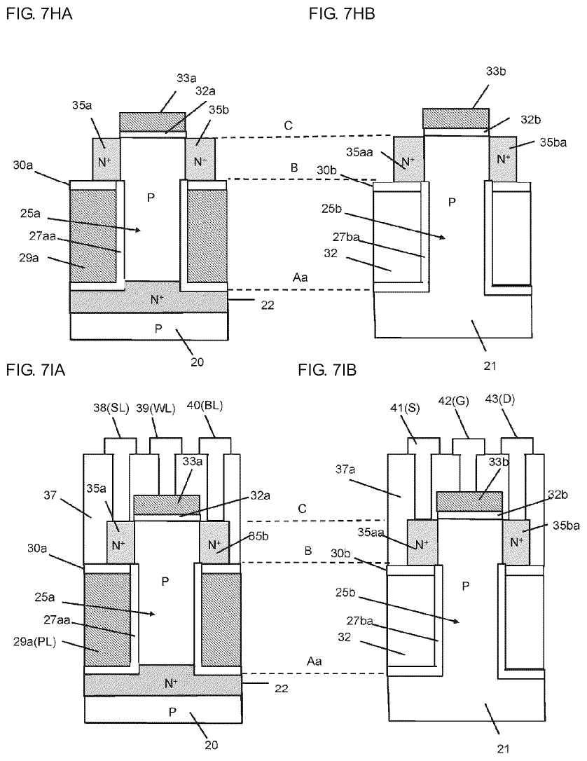

The structure of a memory cell according to this embodiment will be described with reference to FIG. 1. A write mechanism of the memory cell according to the embodiment will be described with reference to FIGS. 2A, 2B, and 2C. A data erase mechanism of the memory cell according to the embodiment will be described with reference to FIGS. 3A, 3B, and 3C. The structures of a memory cell and a MOS transistor (MOS field-effect transistor, hereinafter referred to as a MOS transistor) of a logic circuit that are formed on the same substrate and disposed on the same substrate, according to the embodiment will be described with reference to FIGS. 4A and 4B, FIGS. 5A and 5B, and FIGS. 6A and 6B. A method for producing a memory cell and a MOS transistor of a logic circuit according to the embodiment, the memory cell and the MOS transistor being illustrated in FIGS. 4A and 4B and formed on the same substrate, will be described with reference to FIGS. 7AA and 7AB to FIGS. 7IA and 7IB.

FIG. 1 illustrates a vertical sectional structure of a semiconductor-element-including memory cell according to an embodiment of the present invention. On a Player substrate 1 (which is an example of “substrate” in the claims), an N⁺ layer 2 (which is an example of “first impurity region” in the claims) containing a donor impurity is disposed (hereinafter, a semiconductor region containing a donor impurity at a high concentration is referred to as an “N⁺ layer”). A first semiconductor pillar (which is an example of “first semiconductor pillar” in the claims) composed of an upper layer of the N⁺ layer 2 and a pillar-shaped P layer 3 containing an acceptor impurity, having a rectangular shape in plan view, and having a pillar shape in a vertical section is disposed. A first insulating layer 4 (which is an example of “first insulating layer” in the claims) is disposed to cover an upper surface of the N⁺ layer 2 on an outer peripheral portion of the P layer 3 in plan view. A first gate insulating layer 5 (which is an example of “first gate insulating layer” in the claims) is disposed to cover the P layer 3. A first gate conductor layer 6 (which is an example of “first gate conductor layer” in the claims) is disposed to surround the first gate insulating layer 5. A second insulating layer 8 (which is an example of “second insulating layer” in the claims) is disposed on the first gate insulating layer 5 and the first gate conductor layer 6. The P layer 3 is constituted by a P layer 3a covered with the first gate insulating layer 5 and a P layer 3b located on the P layer 3a. An N⁺ layer 11a (which is an example of “second impurity region” in the claims) containing a donor impurity at a high concentration is disposed on one side of the P layer 3b. An N⁺ layer 11b (which is an example of “third impurity region” in the claims) is disposed on another side opposite to the N⁺ layer 11a. A second gate insulating layer 9 (which is an example of “second gate insulating layer” in the claims) is disposed to cover the P layer 3b. A second gate conductor layer 10 (which is an example of “second gate conductor layer” in the claims) is disposed to cover the second gate insulating layer 9. The second gate conductor layer 10 preferably has a work function lower than the work function of the first gate conductor layer 6.

The N⁺ layer 11a connects to a source line SL, the N⁺ layer 11b connects to a bit line BL, the second gate conductor layer 10 connects to a word line WL, the first gate conductor layer 6 connects to a plate line PL, and the N⁺ layer 2 connects to a control line CDC. The memory is operated by controlling the electric potentials of the source line SL, the bit line BL, the plate line PL, and the word line WL. In an actual memory device, a large number of the above-described memory cells are two-dimensionally arranged on the P layer substrate 1.

In FIG. 1, the P layer substrate 1 is made of a P-type semiconductor. The P layer substrate 1 may have an impurity concentration distribution therein. The N⁺ layer 2 and the P layer 3 may have an impurity concentration distribution therein. Different impurity concentrations may be set for the Players 3a and 3b.

Alternatively, the N⁺ layer 11a and the N⁺ layer 11b may be formed as P⁺ layers in which positive holes serve as the majority carriers (hereinafter, a semiconductor region containing an acceptor impurity at a high concentration is referred to as a “P⁺ layer”), and the memory may be operated with electron serving as carriers for writing. In this case, the first gate conductor layer 6 is preferably made of a material having a work function lower than the work function of the second gate conductor layer 10.

In FIG. 1, a substrate having a P-well structure, a silicon on insulator (SOI) substrate, or the like may be used as the P layer substrate 1.

The first insulating layer 4 in FIG. 1 may be formed as a single layer together with the first gate insulating layer 5.

The first gate conductor layer 6, the second gate conductor layer 10, and a third gate conductor layer 10a may be conductor layers such as metal layers, alloy layers, or semiconductor layers doped at high concentrations. The first gate conductor layer 6, the second gate conductor layer 10, and the third gate conductor layer 10a may each be formed of a plurality of conductor material layers.

A write operation in the memory cell according to an embodiment of the present invention will be described with reference to FIGS. 2A, 2B, and 2C. For example, poly-Si containing an acceptor impurity at a high concentration (hereinafter, poly-Si containing an acceptor impurity at a high concentration is referred to as “P⁺ poly”) is used as the first gate conductor layer 6 connected to the plate line PL. Poly-Si containing a donor impurity at a high concentration (hereinafter, poly-Si containing a donor impurity at a high concentration is referred to as “N⁺ poly”) is used as the second gate conductor layer 10 connected to the word line WL. As illustrated in FIG. 2A, a MOS transistor in this memory cell operates using, as elements, the N⁺ layer 11a serving as the source, the N⁺ layer 11b serving as the drain, the second gate insulating layer 9 serving as the gate insulating layer, the second gate conductor layer 10 serving as the gate, and the P layer 3b serving as the channel. For example, 0 V is applied to the P layer substrate 1, 0 V is input to the N⁺ layer 11a to which the source line SL is connected, for example, 3 V is input to the N⁺ layer 11b to which the bit line BL is connected, 0 V is input to the first gate conductor layer 6 to which the plate line PL is connected, and 1.5 V is input to the second gate conductor layer 10 to which the word line WL is connected. In the P layer 3b immediately below the second gate insulating layer 9 underlying the second gate conductor layer 10, an inversion layer 12 is partly formed and a pinch-off point 13 is present. In this case, the MOS transistor including the second gate conductor layer 10 operates in the saturation region.

As a result, in the MOS transistor including the second gate conductor layer 10, the electric field becomes maximum in the boundary region between the pinch-off point 13 and the N⁺ layer 11b and, in this region, the impact ionization phenomenon occurs. As a result of this impact ionization phenomenon, electrons accelerated from the N⁺ layer 11a to which the source line SL is connected toward the N⁺ layer 11b to which the bit line BL is connected collide with the Si lattice, and electron-positive hole pairs are generated by the kinetic energy. The generated positive holes 14a diffuse toward regions having lower positive hole concentrations in accordance with their concentration gradient. Some of the generated electrons flow to the second gate conductor layer 10, but most of the generated electrons flow to the N⁺ layer 11b connected to the bit line BL. Note that, instead of causing the impact ionization phenomenon, a gate-induced drain-leakage (GIDL) current may be caused to flow to generate a group of positive holes 14a (refer to, for example, E. Yoshida, T, Tanaka, “A Capacitorless 1T-DARM Technology Using Gate-Induced Drain-Leakage (GIDL) Current for Low-Power and High-Speed Embedded Memory”, IEEE Trans, on Electron Devices vol. 53, pp. 692-697 (2006)).

FIG. 2B illustrates the group of positive holes 14b stored in the P layer 3a, immediately after the writing, when the word line WL, the bit line BL, the plate line PL, and the source line SL are at 0 V. Initially, the concentration of the generated positive holes is high in the region of the P layer 3b, and the positive holes move toward the P layer 3a by diffusion in accordance with their concentration gradient. Furthermore, since P⁺ poly having a work function higher than the work function of N⁺ poly is used as the first gate conductor layer 6, the group of positive holes 14b is stored at a higher concentration in regions of the P layer 3a, the regions being close to the first gate insulating layer 5. As a result, the P layer 3a has a positive hole concentration higher than the positive hole concentration of the P layer 3b. Since the P layer 3a and the P layer 3b are electrically connected together, the P layer 3a that substantially serves as a substrate of the MOS transistor including the second gate conductor layer 10 is charged to a positive bias. The group of positive holes 14b moves toward the N⁺ layer 11a, the N⁺ layer 11b, or the N⁺ layer 2 and gradually recombines with electrons; however, the threshold voltage of the MOS transistor including the second gate conductor layer 10 is lowered by the positive substrate-bias effect due to the group of positive holes 14b stored in the P layer 3a. Thus, as illustrated in FIG. 2C, the MOS transistor including the second gate conductor layer 10 to which the word line WL is connected has a lowered threshold voltage. This write state is assigned to logical storage data “1”. Note that the above voltage conditions applied to the bit line BL, the source line SL, the word line WL, and the plate line PL are an example for performing the write operation, and alternatively, other voltage conditions under which the write operation can be performed may be employed.

In FIGS. 2A, 2B, and 2C, a description has been made using, as an example of a combination of the first gate conductor layer 6 and the second gate conductor layer 10, a combination of P⁺ poly (work function: 5.15 eV) and N⁺ poly (work function: 4.05 eV). Alternatively, the combination may be laminated structures of metals, nitrides of metals, or alloys of the metals (including silicides), such as Ni (work function: 5.2 eV) and N⁺ poly, Ni and W (work function: 4.52 eV), or Ni and TaN (work function: 4.0 eV)/W/TiN (work function: 4.7 eV). Alternatively, the first gate conductor layer 6 and the second gate conductor layer 10 may be formed of the same conductor layer, and the drive voltage may be changed to perform the above write operation. For example, during data retention, such a state can be achieved by using a first gate conductor layer 6 and a second gate conductor layer 10 having the same work function, setting the bit line BL, the word line WL, and the source line SL to 0 V, and applying −0.5 V to the plate line PL. This also provides similar advantages.

Next, an erase operation mechanism will be described with reference to FIGS. 3A, 3B, and 3C. FIG. 3A illustrates a state, prior to an erase operation, immediately after the group of positive holes 14b generated by impact ionization in the previous cycle and stored are stored mainly in the P layer 3a. As illustrated in FIG. 3B, at the time of the erase operation, a negative voltage VERA is applied to the source line SL. The voltage of the plate line PL is set to 2 V. Here, VERA is, for example, −0.5 V. As a result, regardless of the initial electric potential value of the P layer 3a, the PN junction between the P layer 3b and the N⁺ layer 11a to which the source line SL is connected and which serves as the source is forward biased. As a result, the group of positive holes 14b generated by impact ionization in the previous cycle and stored mainly in the P layer 3a moves to the N⁺ layer 11a connected to the source line. As a result of application of a voltage of 2 V to the plate line PL, an inversion layer 16 is formed at the interface between the first gate insulating layer 5 and the P layer 3a and in contact with the N⁺ layer 2. Thus, the positive holes 14b stored in the P layer 3a flow from the P layer 3a to the N⁺ layer 2 and the inversion layer 16 and recombine with electrons. As a result, the positive hole concentration of the P layer 3a decreases with time, and the threshold voltage of the MOS transistor becomes higher than that at the time of writing of “1”, resulting in a return to the initial state. Thus, as illustrated in FIG. 3C, the MOS transistor including the second gate conductor layer 10 to which the word line WL is connected returns to the initial threshold. This erase state of the memory is assigned to logical storage data “0”. At the time of this erasing of data, in order to reliably perform the data erase operation, the electron-positive hole recombination area is substantially increased compared with the time of storage of data.

At the time of erasing of data, when, for example, 2 V is applied to the plate line PL, the N⁺ layer 11a, the N⁺ layer 11b, and the N⁺ layer 2 can be electrically connected together by the inversion layer 16 to shorten the data erase time. In this case, the thickness of each of the first insulating layer 4 and the second insulating layer 8 is preferably substantially the same as the thickness of the first gate insulating layer 5.

The above voltage conditions applied to the bit line BL, the source line SL, the word line WL, and the plate line PL are an example for performing the erase operation, and alternatively, other voltage conditions under which the erase operation can be performed may be employed. For example, although an example in which the first gate conductor layer 6 is biased to 2 V has been described above, at the time of erasing, for example, when the bit line BL is set to 0.2 V, the source line SL is set to 0 V, and the first and second gate conductor layers 6 and 10 are biased to 2 V, inversion layers in which electrons serve as the majority carriers can be formed at the interface between the P layer 3a and the first gate insulating layer 5 and at the interface between the P layer 3b and the second gate insulating layer 9. As a result, the electron-positive hole recombination area can be increased. Furthermore, when a current in which electrons serve as the majority carrier is caused to flow between the bit line BL and the source line SL, the erase time can also be further actively shortened.

The first gate conductor layer 6 may be divided into two parts in plan view and driven synchronously or asynchronously such that the above-described operation can be performed. Alternatively, the first gate conductor layer 6 may be divided into two parts in a perpendicular direction and driven synchronously or asynchronously such that the above-described operation can be performed. This also applies to the other embodiments.

The structure and the operation mechanism according to this embodiment have the following features.
(1) In the MOS transistor including the second gate conductor layer 10 to which the word line WL is connected, since the P layer 3b is electrically connected to the P layer 3a, the capacitance for storing the generated group of positive holes 14a can be freely changed by adjusting the volume of the P layer 3a. Specifically, in order to increase the retention time, for example, the depth of the P layer 3a may be increased. Thus, the property of retaining stored data can be improved.
(2) Compared with the volume of the P layer 3a where the group of positive holes 14b, which are signals, is mainly stored, the area of contact with the N⁺ layer 2, the N⁺ layer 11a, and the N⁺ layer 11b involved in recombination with electrons can be intentionally reduced. As a result, recombination of positive holes 14b, which are signal charges, with electrons can be suppressed, and the retention time of the stored group of positive holes 14b can be increased.
(3) Furthermore, since the first gate conductor layer 6 is made of P+ poly, the stored positive holes 14b are stored near the interface with the P layer 3a, which is in contact with the first gate insulating layer 5. Thus, the group of positive holes 14b can be stored in regions apart from contact regions between the N⁺ layer 11a or the N⁺ layer 11b and the P layer 3b, which are the PN junction regions where recombination of electrons and positive holes is caused, to thereby achieve stable storage of the group of positive holes 14b. As a result, for the memory element, the effect of substrate bias is enhanced, the data retention time is increased, and the voltage margin of the operation of writing “1” is increased. As illustrated in FIGS. 3A, 3B, and 3C, in the data erase operation, at the time of erasing of data, the electron-positive hole recombination area is substantially increased compared with the time of storage of data. As a result, the state in which the logical information data “0” is stable can be provided in a short time. Thus, the operation speed of the memory element is improved.
(4) According to this embodiment, the P layer 3a is electrically connected to the P layer substrate 1 and the N⁺ layer 2. Furthermore, the electric potential of the P layer 3a can be controlled by the voltage applied to the first gate conductor layer 6. Thus, in the write operation and in the erase operation, unlike the SOI structure, for example, during the operation of the MOS transistor, instability of the substrate bias in the floating state and full depletion of a semiconductor portion under the second gate insulating layer 9 do not occur. Therefore, the threshold, the driving current, and the like of the MOS transistor are less likely to be affected by the operation state. Accordingly, regarding properties of the MOS transistor, voltages relating to desired memory operations can be set in wide ranges by adjusting the thickness, the type of the impurity, the impurity concentration, and the profile of the P layer 3b, the impurity concentration and the profile of the P layer 3, the thickness and the material of the second gate insulating layer 9, and the work functions of the second gate conductor layer 10 and the first gate conductor layer 6. In addition, the region under the MOS transistor is not fully depleted and a depletion layer extends in the depth direction of the P layer 3b, and thus, in the floating body, coupling of the gate electrode due to the word line, which is a drawback of a capacitor-less DRAM, substantially does not affect the MOS transistor. Specifically, according to this embodiment, the memory can be designed to have a wide voltage margin of the operation.
(5) Moreover, this embodiment is advantageous in that malfunction of memory cells is prevented. In operations of memory cells, unnecessary voltages are applied, due to the control of the voltage of a target cell, to electrodes of some of non-target cells in the cell array, and malfunction occurs, which is a serious problem (for example, Takashi Ohasawa and Takeshi Hamamoto, “Floating Body Cell-a Novel Body Capacitorless DRAm Cell”, Pan Stanford Publishing (2011)). Specifically, the problem refers to a phenomenon in which a cell in which “1” has been written is changed to “0” by an operation of another cell, or a cell in which “0” has been written is changed to “1” by an operation of another cell (hereinafter, the phenomenon due to this malfunction is referred to as disturb failure). According to this embodiment, when “1” is originally written as data information, the amount of group of positive holes 14b stored can be increased by adjusting the depth of the P layer 3a relative to the amount of electron-positive hole recombination caused by a transistor operation; therefore, even under conditions under which disturb failure occurs in existing memories, a change in the threshold of the MOS transistor is less likely to be affected, and the failure is less likely to occur. When “0” is originally written as data information, even when positive holes are unintentionally generated by a transistor operation at the time of reading, the positive holes immediately diffuse into the P layer 3a. Thus, similarly, when the P layer 3a has a large depth, the ratio of change in the positive hole concentration of the P layer 3a and the P layer 3b as a whole is low. Also in this case, the threshold of the MOS transistor is less likely to be affected, and the probability of the occurrence of disturb failure can be reduced compared with existing memories. Thus, according to this embodiment, there is provided a structure resistant to the disturb failure of the memory.
(6) In plan view of this memory cell, one memory cell region corresponds to a single MOS transistor composed of the second gate insulating layer 9, the second gate conductor layer 10, the P layer 3b, and the N⁺ layers 11a and 11b. That is, a signal storage portion composed of the first gate conductor layer 6, the first gate insulating layer 5, the P layer 3a, and the N⁺ layer 11a that retain the positive holes 14b serving as signal charges does not increase the memory cell area. This achieves a higher degree of integration of memory cells.

The structures of a memory cell and a MOS transistor of a logic circuit that are formed on the same substrate, according to the embodiment will be described with reference to FIGS. 4A and 4B. FIG. 4A illustrates a sectional structure of a memory cell. FIG. 4B illustrates a sectional structure of a MOS transistor of a logic circuit formed on the same substrate as that of the memory cell. In FIGS. 4A and 4B, components that are the same as those illustrated in FIG. 1 are assigned the same reference numerals.

The memory cell structure illustrated in FIG. 4A is the same as that in FIG. 1. As illustrated in FIG. 4B, a P layer 3A (which is an example of “second semiconductor pillar” in the claims) standing, in a perpendicular direction, on a P layer substrate 1a connecting to a P layer substrate 1 (which is an example of “substrate” in the claims), having a rectangular shape in plan view, and having a pillar shape in a vertical section is disposed. An insulating layer 4a (which is an example of “third insulating layer” in the claims) is disposed on the P layer substrate 1a in an outer peripheral portion of the P layer 3A. An insulating layer 5a and an insulating layer 13 (which is an example of “intermediate material layer” in the claims) are disposed so as to cover the periphery of a P layer 3aa which is a lower part of the P layer 3A. An insulating layer 8a (which is an example of “fourth insulating layer” in the claims) is disposed on the insulating layers 5a and 13. A third gate insulating layer 9a (which is an example of “third gate insulating layer” in the claims) is disposed to cover an upper surface of a P layer 3ba which is an upper portion of the P layer 3A. A third gate conductor layer 10a (which is an example of “third gate conductor layer” in the claims) is disposed to cover the third gate insulating layer 9a. An N⁺ layer 11aa (which is an example of “fourth impurity region” in the claims) and an N⁺ layer 11ba (which is an example of “fifth impurity region” in the claims) are disposed at both ends of the P layer 3ba. The third gate conductor layer 10a connects to a gate line G, the N⁺ layer 11aa connects to a source line S, and the N⁺ layer 11ba connects to a drain line D. The insulating layers 4a, 5a, 8a, and 13 may be layers made of different materials, the insulating layer 4a and the insulating layer 5a may be layers made of the same material, or the insulating layer 13 may be formed as a conductor layer. Thus, a material layer (which is an example of “first material layer” in the claims) formed of the insulating layers 4a, 5a, 8a, and 13 can be in a form including a conductor material or a form that does not include a conductor material.

In FIGS. 4A and 4B, the P layer substrate 1a connects to the Player substrate 1, and an upper surface of the P layer substrate 1a is substantially flush with an upper surface (line A in the figures) of the N⁺ layer 2. An upper surface of the second insulating layer 8 is substantially flush with an upper surface (line B in the figures) of the insulating layer 8a. An upper surface of the P layer 3b is substantially flush with an upper surface (line C in the figures) of the P layer 3ba. An upper surface of the P layer 3 is substantially flush with an upper surface (line C in the figures) of the P layer 3A. In contrast, a bottom portion of the P layer 3 may be located at a position different from the position of a bottom portion of the P layer 3A in accordance with the design requirements. Similarly, the upper surface of the P layer 3 may be located at a position different from the position of the upper surface of the P layer 3A in accordance with the design requirements. For example, when a MOS transistor composed of the P layer 3b, the N⁺ layers 11a and 11b, the second gate insulating layer 9, and the second gate conductor layer 10 is a planar MOS transistor and a MOS transistor composed of the P layer 3ba, the N⁺ layers 11aa and 11ba, the third gate insulating layer 9a, and the third gate conductor layer 10a is a fin MOS transistor, the upper surface of the P layer 3 is preferably located below or flush with the upper surface of the Player 3A. This also applies to the other embodiments.

The differences in structure between the memory cell in FIG. 4A and the MOS transistor in FIG. 4B are as follows.
(1) The N⁺ layer 2 in the memory cell is not included in the MOS transistor of the logic circuit.
(2) The first gate conductor layer 6 in the memory cell corresponds to the insulating layer 13 in the MOS transistor.

The structure of a MOS transistor composed of the P layer 3b, the N⁺ layers 11a and 11b, the second gate insulating layer 9, and the second gate conductor layer 10 of the memory cell and the structure of a MOS transistor composed of the P layer 3ba, the N⁺ layers 11aa and 11ba, the third gate insulating layer 9a, and the third gate conductor layer 10a of the logic circuit are substantially the same except for the above.

Both the MOS transistors in FIGS. 4A and 4B are formed of the same planar MOS transistors or fin MOS transistors. One or both of the MOS transistors in FIGS. 4A and 4B may be formed of a MOS transistor in which the channel has a U-shaped section. In this case, N⁺ layers corresponding to the N⁺ layers 11a, 11b, 11aa, and 11ba are formed to connect to both ends of the U-shaped channel. Although the MOS transistors in the memory and the logic circuit may have different structural parameters, the MOS transistors have substantially the same basic structure. In the region of the logic circuit, as a CMOS circuit, a P-channel MOS transistor is formed together with an N-channel MOS transistor on the same substrate connecting to the P layer substrate 1. In this case, the N⁺ layers 11aa and 11ba are formed as P⁺ layers, and, for example, the structural dimensions, impurity concentrations, the formation of an N-layer well layer, and an isolation region from the N-channel MOS transistor are changed in accordance with the design requirements; however, the relation of the upper and lower positions (line A and line C in the figures) of the Players 3aa and 3ba and the position of the bottom portion (line B in the figures) of the MOS transistor in the perpendicular direction is substantially the same as that of the N-channel MOS transistor. In FIG. 4A, a P⁻-well layer having an acceptor impurity concentration lower than that of the P layer substrate 1 may be provided between the N⁺ layer 2 and the P layer substrate 1.

The MOS transistors of the memory cell and the logic circuit according to this embodiment have the following features.
(1) The upper surface of the insulating layer 8 and the upper surface of the insulating layer 8a (line B in the figures) are located at substantially the same position. This simplifies the process of producing the MOS transistor including, as the channel, the P layer 3b of the memory cell and the MOS transistor of the logic circuit. This also applies to the other embodiments.
(2) Furthermore, the bottom portion of the pillar-shaped P layer 3 including an upper portion of the N⁺ layer 2 of the memory cell is located at the same position as the bottom portion (line A in the figures) of the pillar-shaped P layer 3A of the MOS transistor of the logic circuit. This contributes to simplification of the process of producing the MOS transistors of the memory cell and the logic circuit. This also applies to the other embodiments.
(3) Furthermore, the upper surface of the pillar-shaped P layer 3 of the memory cell and the upper surface of the pillar-shaped P layer 3A of the MOS transistor of the logic circuit (line C in the figures) are located at the same position. This contributes to simplification of the process of producing the MOS transistors of the memory cell and the logic circuit. This also applies to the other embodiments.
(4) The P layer 3a in which the group of positive holes 14b serving as signal charges of the memory cell is stored can be formed without adding a special step to the production of the MOS transistor in the logic circuit region. This simplifies the production of a memory device including a memory cell and a logic circuit.

The structures of a memory cell and a MOS transistor of a logic circuit that are formed on the same substrate, according to the embodiment will be described with reference to FIGS. 5A and 5B. FIG. 5A illustrates a sectional structure of a memory cell. FIG. 5B illustrates a sectional structure of a MOS transistor of a logic circuit formed on the same substrate as that of the memory cell. In FIGS. 5A and 5B, components that are the same as those illustrated in FIGS. 4A and 4B are assigned the same reference numerals.

The sectional structure of the memory cell illustrated in FIG. 5A is the same as that illustrated in FIG. 4A. In the MOS transistor of the logic circuit illustrated in FIG. 5B, the insulating layers 4a, 5a, 8a, and 13 in FIG. 4B are formed of a single insulating layer 19. In the memory cell, the insulating layers 4 and 8 need to be provided on and under the first gate conductor layer 6 which is a conductor layer. In contrast, in the MOS transistor of the logic circuit, since the portion corresponding to the first gate conductor layer 6 is an insulating layer, the portion may be formed of the single insulating layer 19 surrounding the P layer 3aa.

Note that, in the formation of the insulating layer 19, at least two or more of the insulating layers 4a, 5a, 8a, and 13 in FIG. 4B may be formed at the same time. For example, the insulating layer 5a is left, and the insulating layers 4a, 13, and 8a may be formed at the same time. Alternatively, the insulating layers 4a and 5a may be formed at the same time. In this case, the insulating layers 4, 4a, 5, and 5a are formed at the same time. Alternatively, the insulating layers 13 and 8a may be formed at the same time.

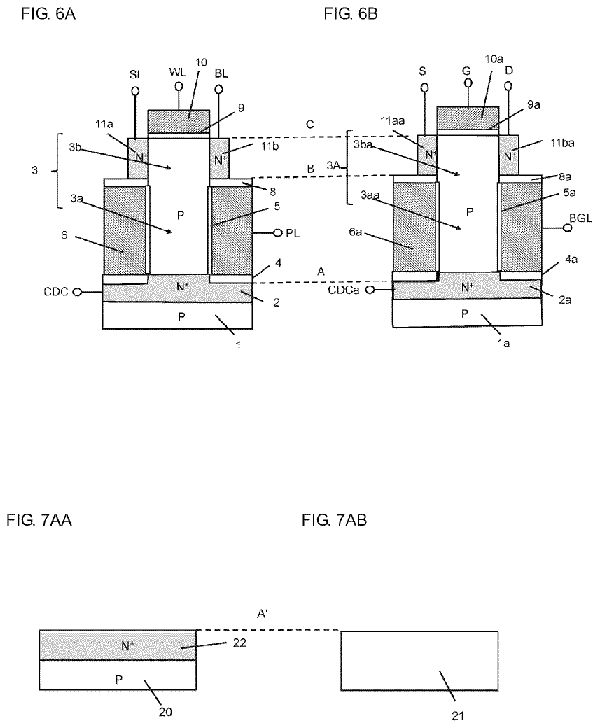

The structures of a memory cell and a MOS transistor of a logic circuit that are formed on the same substrate, according to the embodiment will be described with reference to FIGS. 6A and 6B. FIG. 6A illustrates a sectional structure of a memory cell. FIG. 6B illustrates a sectional structure of a MOS transistor of a logic circuit formed on the same substrate as that of the memory cell. In FIGS. 6A and 6B, components that are the same as those illustrated in FIGS. 4A and 4A or FIGS. 5A and 5B are assigned the same reference numerals.

The sectional structure of the memory cell illustrated in FIG. 6A is the same as that illustrated in FIG. 4A. The MOS transistor of the logic circuit illustrated in FIG. 6B has the same basic structure as that in FIG. 6A. However, in FIG. 6A, the first gate conductor layer 6 connects to the plate line PL, and the N⁺ layer 2 is connected to the control line CDC. On the other hand, in FIG. 6B, a back gate conductor layer 6a connects to a back gate line BGL, and in FIG. 6B, an N⁺ layer 2a is connected to a control line CDCa. The voltage applied to the back gate line BGL is controlled to thereby control the voltage of the P layer 3aa. Thus, the threshold voltage of the MOS transistor composed of the P layer 3ba located on the P layer 3aa, the third gate insulating layer 9a, the third gate conductor layer 10a, and the N⁺ layers 11aa and 11ba is changed. In this manner, threshold voltages of a plurality of MOS transistors in the logic circuit can be set to values as desired by changing the voltage applied to the back gate line BGL. Note that, in FIG. 6B, the N⁺ layer 2a may not be provided. For example, the voltage applied to the back gate line BGL is driven under the condition under which the entire P layer 3aa is depleted. For this purpose, the acceptor impurity concentration of the P layer 3aa may be lower than the acceptor impurity concentration of the P layer 3ba. The electric potential of the P layer 3aa surrounded by the back gate conductor layer 6a may be controlled by the voltage applied to the back gate conductor layer 6a.

In an actual logic circuit, MOS transistors having a plurality of threshold voltages are formed. This change in the threshold voltage is achieved by, for example, a method of using, as the third gate conductor layer 10a, a metal layer having a different work function or a method of changing the impurity concentration of the P layer 3ba. In contrast, according to this embodiment, the threshold voltage can be set by merely changing the voltage applied to the back gate line BGL. In addition, the memory cell and the MOS transistor of the logic circuit have the same basic structure. This simplifies the production method and leads to a reduction in the cost of the memory device. Moreover, by changing the voltage applied to the back gate conductor layer 6a depending on the operation period, for example, the circuit power consumption can be reduced.

A process of forming a memory cell and a MOS transistor of a logic circuit on the same substrate will be described with reference to FIGS. 7AA and 7AB to FIGS. 7IA and 7IB. Note that, in the figures, in a memory cell region illustrated in figures suffixed with A and a logic circuit region illustrated in figures suffixed with B, distances and positional relationships in the horizontal direction between the two regions may be arbitrary; however, positional relationships in the height direction are as illustrated in the figures.

As illustrated in FIGS. 7AA and 7AB, in the memory cell region in FIG. 7AA, an N⁺ layer 22 is formed as an upper layer of a P layer substrate 20. In the logic circuit region illustrated in FIG. 7AB, a P layer substrate 21 connecting to the P layer substrate 20 illustrated in FIG. 7AA and having a surface that is flush with an upper surface of the N⁺ layer 22 at a height of line A′ is disposed. The N⁺ layer 22 is formed by, for example, ion implantation into the P layer substrate 20, plasma impurity doping, or an epitaxial crystal growth method. In the epitaxial crystal growth method, the P layer 20 is etched to a predetermined depth, and subsequently, epitaxial crystal growth of a semiconductor layer containing a donor impurity, and a step of making the surface of the memory cell region and the surface of the logic circuit region flush with each other, for example, surface chemical mechanical polishing (CMP) are performed.

Next, as illustrated in FIGS. 7BA and 7BB, P layers 23a and 23b are formed on the N⁺ layer 22 and on the P layer 21, respectively, at the same time by, for example, an epitaxial crystal growth method. Subsequently, a mask material layer 24a is formed on the P layer 23a, and a mask material layer 24b is formed on the P layer 23b.

Next, as illustrated in FIGS. 7CA and 7CB, the P layers 23a and 23b are etched by, for example, a reactive ion etching (RIE) method using the mask material layers 24a and 24b as a mask such that an etching bottom portion is positioned at a height of line A to form P layers 25a and 25b having a rectangular shape in plan view and having a pillar shape in a vertical section. The etching is performed such that, in the memory cell region, the etching bottom portion is positioned at an upper portion of the N⁺ layer 22a. As a result, the surface of the outer peripheral portion of the P layer 25a in the memory cell region and the surface of the outer peripheral portion of the P layer 25b in the logic circuit region are substantially flush with each other at the height of line A. In addition, the surfaces of top portions of the P layer 25a and the P layer 25b are substantially flush with each other at a height of line C. In actual RIE, for example, the difference in impurity concentration between the N⁺ layer 22a and the P layer 21 and the difference between positions where the P layers 25a and 25b stand cause a slight difference in etching rate. This causes a slight difference between the position of the surface of the outer peripheral portion of the P layer 25a in the memory cell region and the position of the surface of the outer peripheral portion of the P layer 25b in the logic circuit region; however, the surfaces are substantially flush with each other at the height of line A. Similarly, the top portion of the P layer 25a and the top portion of the P layer 25b are substantially flush with each other at the height of line C.

Next, as illustrated in FIGS. 7DA and 7DB, a surface layer of the P layer 25a and a surface layer of the N⁺ layer 22 are oxidized to form an oxide insulating layer 27a, and at the same time, a surface layer of the pillar-shaped P layer 25b and a surface layer of the P layer substrate 21 are oxidized to form an oxide insulating layer 27b. The oxide insulating layers 27a and 27b may be formed by another method such as atomic layer deposition (ALD). Alternatively, on the outer peripheral portions and side surfaces of the P layers 25a and 25b, an insulating layer 4 and an insulating layer 4a and a first gate insulating layer 5 and an insulating layer 5a that are separated from each other may be separately formed, as illustrated in FIGS. 4A and 4B.

Next, as illustrated in FIGS. 7EA and 7EB, for example, poly-Si layers 29a and 29b containing a donor or acceptor impurity in a large amount are formed so as to surround lower portions of the oxide insulating layers 27a and 27b covering the pillar-shaped P layers 25a and 25b. Subsequently, insulating layers 30a and 30b are formed on the poly-Si layers 29a and 29b at the same time. Thus, the surfaces of the insulating layers 30a and 30b are substantially flush with each other at a height of line B. The insulating layers 30a and 30b may be formed by another method, for example, by oxidizing the poly-Si layers 29a and 29b.

Next, as illustrated in FIGS. 7FA and 7FB, the poly-Si layer 29b in the logic circuit region is removed. Subsequently, an insulating layer 32 such as a SiO₂ layer is formed by, for example, a chemical vapor deposition (CVD) method in the resulting space from which the poly-Si layer 29b has been removed. The insulating layer 32 may be formed of another insulating material layer other than the SiO₂ layer.

Next, as illustrated in FIGS. 7GA and 7GB, the exposed oxide insulating layers 27a and 27b are etched to form oxide insulating layers 27aa and 27ba. The mask material layers 24a and 24b are removed. A second gate insulating layer 32a and a third gate insulating layer 32b are formed so as to cover upper surfaces of top portions of the P layers 25a and 25b or exposed upper surfaces and side surfaces of the P layers 25a and 25b. Subsequently, a second gate conductor layer 33a covering the second gate insulating layer 32a and a third gate conductor layer 33b covering the third gate insulating layer 32b are formed. The second gate conductor layer 33a and the third gate conductor layer 33b may be formed by a process such as a gate-first process or a gate-last process (refer to, for example, Martin M. Frank, “High-k/Metal Gate Innovations Enabling Continued CMOS Scaling” Proc. of the 41th European Solid-state Device Research Conference pp. 50-58 (2011)).

Next, as illustrated in FIGS. 7HA and 7HB, N⁺ layers 35a and 35b are formed at both ends of top portions of the P layer 25a and on the insulating layer 30a. Similarly, N⁺ layers 35aa and 35ba are formed at both ends of top portions of the P layer 25b and on the insulating layer 30b. Lightly doped drain (LDD) regions may be formed between the P layer 25a and the N⁺ layer 35a and between the P layer 25a and N⁺ layer 35b, and between the P layer 25b and the N⁺ layer 35aa and between the P layer 25b and N⁺ layer 35ba.

Next, as illustrated in FIGS. 7IA and 7IB, the entire structure is covered with insulating layers 37 and 37a. Subsequently, a wiring layer 38 connecting to the N⁺ layer 35a, a wiring layer 39 connecting to the second gate conductor layer 33a, a wiring layer 40 connecting to the N⁺ layer 35b, a wiring layer 41 connecting to the N⁺ layer 35aa, a wiring layer 42 connecting to the third gate conductor layer 33b, and a wiring layer 43 connecting to the N⁺ layer 35ba are formed. The wiring layer 38 connects to a source line SL, the wiring layer 39 connects to a word line WL, the wiring layer 40 connects to a bit line BL, the wiring layer 41 connects to a source line S, the wiring layer 42 connects to a gate line G, and the wiring layer 43 connects to a drain line D. The poly-Si layer 29a connects to a plate line PL. Thus, a memory cell and an N-channel MOS transistor are formed on the P layer substrates 20 and 21 that are connected together.

In FIGS. 7AB to 7IB, a method for producing an N-channel MOS transistor in the logic circuit region has been described. In the actual logic circuit region, a P-channel MOS transistor is also formed on the P layer substrate 21. In the P-channel MOS transistor, the N⁺ layers 35aa and 35ba in the N-channel MOS transistor are formed as P⁺ layers containing an acceptor impurity in a large amount, and the materials, the thicknesses, and the like of the third gate insulating layer 32b and the third gate conductor layer 33b may be changed in some cases in accordance with the design requirements; however, the basic structure of the P-channel MOS transistor is the same as that of the N-channel MOS transistor. A bottom portion of a pillar-shaped semiconductor layer corresponding to the P layer 25b on which the P-channel MOS transistor is formed is located substantially at a height of line Aa, and a top portion of the pillar-shaped semiconductor layer is located substantially at a height of line C. In addition, a bottom portion of the P-channel MOS transistor is located substantially at a height of line B as in the bottom portion of the N-channel MOS transistor. The pillar-shaped semiconductor layer of the P-channel MOS transistor may be an N layer having a low donor impurity concentration or a P layer having a low acceptor impurity concentration. For electrical isolation from the N-channel MOS transistor, a well structure may be used.

In FIGS. 7AA and 7AB to FIGS. 7IA and 7IB, the N⁺ layers 35a and 35b in the memory cell region and the N⁺ layers 35aa and 35ba in the logic circuit region are arranged in the same direction. Alternatively, the N⁺ layers 35a and 35b and the N⁺ layers 35aa and 35ba may be arranged in different directions in accordance with the design requirements. This also applies to the other embodiments.

The boundary between the N⁺ layer 22 and the P layer 25a may be located higher than or lower than the bottom surface of the first gate conductor layer 29a in the perpendicular direction. This also applies to the other embodiments.

In the formation of the P layers 25a and 25b, a material layer serving as the first gate conductor layer 29a and insulating layers on and under the material layer are deposited so as to have a layer structure, holes extending through these layers are then formed, and the P layers 25a and 25b may be formed by, for example, a selective epitaxial crystal growth method or a metal-induced lateral crystallization (MILC) method (refer to, for example, H. Miyagawa et al., “Metal-Assisted Solid-Phase Crystallization Process for Vertical Monocrystalline Si Channel in 3D Flash Memory”, IEDM19 digest paper, pp. 650-653 (2019)). The first gate conductor layer 29a may be formed by etching a dummy gate material formed at first, and subsequently embedding the first gate conductor layer 29a in the resulting space.

The production method according to this embodiment illustrated in FIGS. 7AA and 7AB to FIGS. 7IA and 7IB has the following features.
(1) The pillar-shaped P layer 25a including an upper portion of the N⁺ layer 22 of the memory cell and the pillar-shaped P layer 25b of the MOS transistor of the logic circuit can be formed, by performing etching at the same time by the RIE method, such that the bottom surface and the top portion of the first semiconductor pillar and those of the second semiconductor pillar are located at the same positions. Thus, the process can be simplified.
(2) Except for the steps of forming the first gate conductor layer 29a of the memory cell and the insulating layer 32 of the logic circuit, the steps before and after the formation of the first gate conductor layer 29a and the insulating layer 32 of the logic circuit can be performed as common steps. Thus, the process can be simplified.
(3) The MOS transistor of the memory cell formed on the upper portion of the P layer 25a and the MOS transistor of the logic circuit formed on the upper portion of the P layer 25b are formed at the same height in the perpendicular direction.

The P layer substrate 1 in FIG. 1 may be formed of a semiconductor or an insulating layer. Alternatively, the P layer substrate 1 may be a well layer. This also applies to the other embodiments illustrated in FIGS. 2A to 2C to FIGS. 7IA to 7IB.

In FIGS. 2A to 2C, a description has been made of an example in which P⁺ poly is used as the first gate conductor layer 6, and N⁺ poly is used as the second gate conductor layer 10. As long as the first gate conductor layer 6 has a work function higher than the work function of the second gate conductor layer 10, the gate conductor layers may be a combination such as P⁺ poly (5.15 eV)/laminate of W and TiN (4.7 eV), P⁺ poly (5.15 eV)/laminate of silicide and N⁺ poly (4.05 eV), or TaN (5.43 eV)/laminate of W and TiN (4.7 eV). In the case of using an N-type semiconductor as the P layer 3, as long as the first gate conductor layer 6 has a work function lower than the work function of the second gate conductor layer 10, similar advantages can be provided, for example, when N⁺ poly is used as the first gate conductor layer 6 and P⁺ poly is used as the second gate conductor layer 10. The first gate conductor layer 6 and the second gate conductor layer 10 may be made of a semiconductor, a metal, or a compound thereof. This also applies to the other embodiments.

In FIG. 1, the vertical sectional shape of the P layer 3 has been described as being a rectangular shape; alternatively, the vertical sectional shape may be a trapezoidal shape. This also applies to the other embodiments. The horizontal section of the P layer 3 may have a square shape or an oblong shape. This also applies to the other embodiments.

In FIG. 1, the N⁺ layer 2 is illustrated as connecting to adjacent memory cells; alternatively, the N⁺ layer 2 may be present only in a bottom portion of the P layer 3. In this case, the N⁺ layer is not connected to the control line CDC. Also in this case, a normal memory operation can be performed. This also applies to the other embodiments.

When the N⁺ layer 2 illustrated in FIG. 1 connects to adjacent memory cells and connects to the control line CDC, a conductor layer may be provided on a part or over the entire surface of the N⁺ layer 2 on the outer peripheral portion of the P layer 3 in plan view. This also applies to the other embodiments.

The N⁺ layer 35a connecting to the source line SL in the memory cell illustrated in FIGS. 7IA and 7IB may be shared by cells adjacent to each other. The N⁺ layer 35b connecting to the bit line BL may be shared by cells adjacent to each other. This achieves a higher degree of integration of the memory cell region. This also applies to the other embodiments.

In FIG. 1, the first gate conductor layer 6 and the second gate conductor layer 10 may be divided into a plurality of parts and driven synchronously or asynchronously. Also in this case, a normal memory operation is performed. This also applies to the other embodiments.

The P layer substrate 1 in FIG. 1 may be a silicon on insulator (SOI) substrate, a substrate having a well structure, or the like. A MOS transistor circuit isolated by an insulating layer may be provided under the N⁺ layer 2. This also applies to the other embodiments.

In FIGS. 7AA and 7AB to FIGS. 7IA and 7IB, the pillar-shaped P layers 25a and 25b are formed by etching the P layers 23a and 23b using the mask material layers 24a and 24b as an etching mask. Alternatively, for example, a poly-Si layer extending to the entire surface in the horizontal direction is formed, holes are formed in the poly-Si layer, oxide insulating layers 27a and 27b are formed on the side surfaces of the holes, and the pillar-shaped P layers 25a and 25b may then be formed by, for example, an epitaxial crystal growth method. This also applies to the other embodiments.

It is to be understood that various embodiments and modifications of the present invention are possible without departing from the broad spirit and scope of the present invention. The embodiments described above are illustrative examples of the present invention and do not limit the scope of the present invention. The examples and modifications can be appropriately combined. Furthermore, some of constituent features of the above embodiments may be omitted as required, and such embodiments still fall within the technical idea of the present invention.

Use of the memory-element-including semiconductor device according to the present invention can provide a semiconductor device with high performance at a low cost.

What is claimed is:

1. A memory-element-including semiconductor device comprising:
a memory element; and
a MOS transistor,
wherein the memory element includes
a first semiconductor pillar that stands on a substrate in a direction perpendicular to the substrate,
a first impurity region connecting to a bottom portion of the first semiconductor pillar,
a first gate insulating layer in contact with a lower portion of the first semiconductor pillar,
a first gate conductor layer in contact with the first gate insulating layer and composed of one part or two parts in plan view or in the perpendicular direction,
a first insulating layer disposed between the first impurity region and the first gate conductor layer,
a second insulating layer disposed on the first gate conductor layer and surrounding the first semiconductor pillar,
a second gate insulating layer covering, in the perpendicular direction, an upper surface of the first semiconductor pillar located above the first gate insulating layer or the upper surface and both side surfaces continuous with the upper surface,
a second gate conductor layer covering the second gate insulating layer, and
a second impurity region and a third impurity region disposed at both ends of a portion of the first semiconductor pillar, the portion being not covered with the second gate insulating layer, in a horizontal direction,
the MOS transistor includes
a second semiconductor pillar that stands on the substrate in the direction perpendicular to the substrate,
a first material layer surrounding a lower part of the second semiconductor pillar and formed of, from a bottom, a third insulating layer, an intermediate material layer made of an insulating material or a conductor material, and a fourth insulating layer,
a third gate insulating layer covering, in the perpendicular direction, an upper surface of the second semiconductor pillar located above the first material layer or the upper surface and both side surfaces,
a third gate conductor layer covering the third gate insulating layer, and
a fourth impurity region and a fifth impurity region disposed at both ends of a portion of the second semiconductor pillar, the portion being not covered with the third gate insulating layer, in the horizontal direction, and
an upper surface of the second insulating layer and an upper surface of the first material layer are located at substantially the same position in the perpendicular direction.

2. The memory-element-including semiconductor device according to claim 1,
wherein the upper surface of the first semiconductor pillar is substantially flush with or located below the upper surface of the second semiconductor pillar in the perpendicular direction.

3. The memory-element-including semiconductor device according to claim 1,
wherein the intermediate material layer is made of an insulating material.

4. The memory-element-including semiconductor device according to claim 1,
wherein the intermediate material layer is formed of an insulating layer surrounding a lower portion of the second semiconductor pillar and a conductor layer surrounding the insulating layer, and
a voltage that is constant or changes with time is applied to the conductor layer.

5. The memory-element-including semiconductor device according to claim 4, comprising:
a sixth impurity region connecting to the bottom portion of the second semiconductor pillar.

6. The memory-element-including semiconductor device according to claim 1,
wherein the first gate insulating layer and the first insulating layer are made of the same material.

7. The memory-element-including semiconductor device according to claim 1,
wherein a transistor composed of an upper portion of the first semiconductor pillar, the second gate insulating layer, the second gate conductor layer, the second impurity region, and the third impurity region of the memory element is a planar MOS transistor, and the MOS transistor is also a planar MOS transistor.

8. The memory-element-including semiconductor device according to claim 1,
wherein a transistor composed of an upper portion of the first semiconductor pillar, the second gate insulating layer, the second gate conductor layer, the second impurity region, and the third impurity region of the memory element is a fin MOS transistor, and the MOS transistor is also a fin MOS transistor.

9. The memory-element-including semiconductor device according to claim 1,
wherein the first impurity region connects to a bottom portion of a semiconductor pillar of another memory cell adjacent to the first semiconductor pillar.

10. The memory-element-including semiconductor device according to claim 1,
wherein the first impurity region is isolated from an impurity layer in a bottom portion of a semiconductor pillar of another memory cell adjacent to the first semiconductor pillar.

11. The memory-element-including semiconductor device according to claim 1,
wherein the two parts of the first gate conductor layer composed of two parts in the perpendicular direction are configured to be driven synchronously or asynchronously.

12. The memory-element-including semiconductor device according to claim 1,
wherein the two parts of the first gate conductor layer composed of two parts in plan view are configured to be driven synchronously or asynchronously.

13. The memory-element-including semiconductor device according to claim 1,
wherein the first semiconductor pillar, the first and second gate insulating layers, the first to third impurity regions, and the first and second gate conductor layers are configured to perform
a memory write operation of controlling voltages applied to the first impurity region, the second impurity region, the third impurity region, the first gate conductor layer, and the second gate conductor layer to generate, in an upper portion of the first semiconductor pillar, a group of electrons and a group of positive holes by an impact ionization phenomenon using a current flowing between the second impurity region and the third impurity region or by a gate-induced drain-leakage current and cause, of the generated group of electrons and the generated group of positive holes, a portion or entirety of the group of electrons or the group of positive holes serving as majority carriers to remain mainly in the first semiconductor pillar in contact with the first gate insulating layer, and
a memory erase operation of discharging the group of electrons or the group of positive holes serving as the remaining majority carriers from at least the first impurity region, the second impurity region, and the third impurity region.

14. The memory-element-including semiconductor device according to claim 1,
wherein the bottom portion of the first semiconductor pillar and a bottom portion of the second semiconductor pillar are located at substantially the same position in the perpendicular direction.

15. The memory-element-including semiconductor device according to claim 1,
wherein the memory element includes a planar MOS transistor formed with an upper part of the first semiconductor pillar, the second gate insulating layer, the second gate conductor layer, the second impurity region and the third impurity region,
the MOS transistor is a fin MOS transistor, and
the second insulating layer and the first material layer have upper surfaces, respectively, at vertical locations substantially aligned with each other, and the first semiconductor pillar and the second semiconductor pillar have upper surfaces, respectively, at vertical locations substantially aligned with each other.
